(19) United States
(12) Patent Application Publication
(10) Pub. No.: US 2013/0220691 A1
(43) Pub. Date: Aug. 29, 2013

(54) MULTILAYER WIRING SUBSTRATE AND METHOD OF MANUFACTURING THE SAME

(71) Applicant: NGK SPARK PLUG CO., LTD., (US)

(72) Inventor: Kenji SUZUKI, Iwakura-shi (JP)

(73) Assignee: NGK SPARK PLUG CO., LTD., Nagoya-shi (JP)

(21) Appl. No.: 13/774,405

(22) Filed: Feb. 22, 2013

(30) Foreign Application Priority Data
Feb. 28, 2012 (JP) 2012-041851
Dec. 5, 2012 (JP) 2012-266356

(51) Int. Cl. H05K 3/00; H05K 1/11

(52) U.S. Cl. CPC H05K 3/0094; H05K 1/116
USPC 174/266; 29/852

(57) ABSTRACT

Provided is a multilayer wiring substrate comprising a first build-up layer and a second build-up layer including at least one insulating layer and at least one conductor layer, and a supporting substrate that supports the first and second build-up layers on the upper surface and the lower surface thereof, respectively. The multilayer wiring substrate includes a through hole extending between the upper surface side and the lower surface side of the supporting substrate, the through hole including openings on an upper and a lower end side thereof, a through hole conductor which is formed on the inner circumferential surface of the through hole, a conductor layer which is formed as to cover the opening on the upper end side of the through hole, and a conductor layer which is formed in a periphery of the opening on the lower end side of the through hole without covering the opening.

### CROSS REFERENCE TO RELATED APPLICATIONS

The present application claims priority from Japanese Patent Application Nos. 2012-041851 and 2012-266356, which were filed on Feb. 28, 2012 and Dec. 5, 2012, respectively, the disclosures of which are herein incorporated by reference in their entirety.

### BACKGROUND OF THE INVENTION

1. Field of the Invention

The present invention relates to a multilayer wiring substrate formed by alternately laminating a plurality of insulating layers and a plurality of conductor layers and a method of manufacturing the same.

2. Description of Related Art

Multilayer wiring substrates are known in which build-up layers having insulating layers and conductor layers laminated alternately are formed on both sides of a supporting substrate. In such multilayer wiring substrates, a through hole passing through the supporting substrate is formed and a conductor layer is formed on the inner circumferential surface of the through hole, thereby causing a build-up layer formed on the upper surface side of the supporting substrate and a build-up layer formed on the lower surface side thereof to be electrically connected to each other.

In the past, a technique has been known in which after a conductor layer is formed on the inner circumferential surface of a through hole, an insulating resin is embedded in a through hole formed on the inner circumferential side of the conductor layer, and an opening of the through hole after the embedment of the insulating resin is filled up with the conductor layer (see, for example, JP-A-2008-270769). Using this technique, a via conductor can be formed directly above the through hole through the conductor layer that fills up the opening of the through hole, and thus a fine wiring pattern can be formed.

### BRIEF SUMMARY OF THE INVENTION

However, in the technique disclosed in JP-A-2008-270769 mentioned above, there is a problem of requiring a special process for embedding an insulating resin in a through hole that passes through a supporting substrate.

The present invention is contrived in view of such a problem, and an object thereof is to provide a technique capable of forming a via conductor directly above a through hole without adding a special process for embedding the inside of the through hole.

According to a first aspect of the present invention, there is provided a multilayer wiring substrate comprising a first build-up layer and a second build-up layer which are formed by laminating at least one insulating layer and at least one conductor layer; a supporting substrate that supports the first build-up layer and the second build-up layer on an upper surface and a lower surface thereof, respectively; a through hole which is formed to extend between the upper surface side of the supporting substrate and the lower surface side thereof, and including an opening on an upper end side of the through hole that has a larger diameter than that of an opening on a lower end side of the through hole; a through hole conductor which is formed on an inner circumferential surface of the through hole; a coating conductor which is formed so as to cover the opening on the upper end side of the through hole, and is electrically connected to the through hole conductor; and a non-coating conductor which is formed in a periphery of the opening on the lower end side of the through hole without covering the opening on the lower end side, and is electrically connected to the through hole conductor.

In the multilayer wiring substrate having such a configuration, since the through hole extends between the upper surface side of the supporting substrate and the lower surface side thereof, and the through hole conductor is formed on the inner circumferential surface of the through hole, the upper surface side and the lower surface side of the supporting substrate can be electrically connected to each other through the through hole conductor.

The coating conductor formed so as to cover the opening on one end side (upper end side) of the through hole and the non-coating conductor formed in the periphery of the opening on the other end side (lower end side) without covering the opening on the other end side of the through hole are electrically connected to the through hole conductor. That is, the coating conductor disposed on the upper surface side of the supporting substrate is electrically connected to the non-coating conductor disposed on the lower surface side of the supporting substrate. For this reason, the first build-up layer formed on the upper surface of the supporting substrate and the second build-up layer formed on the lower surface of the supporting substrate can be electrically connected to each other through the coating conductor and the non-coating conductor.

In addition, the coating conductor is formed so as to cover the opening on one end side of the through hole. For this reason, a via conductor which is formed on the coating conductor in order to electrically connect the conductor layer disposed above the coating conductor and the non-coating conductor to each other, can be disposed directly above the opening on one end side of the through hole through the coating conductor. Thereby, a fine wiring pattern can be formed above the coating conductor.

Further, the non-coating conductor is formed in the periphery of the opening on the other end side without covering the opening on the other end side of the through hole. For this reason, in a process of laminating the insulating layer on the lower surface of the supporting substrate, inside the through hole can be embedded the insulating layer laminated on the lower surface of the supporting substrate. Thereby, it is possible to eliminate the need for a special process for embedding inside the through hole.

In addition, in the multilayer wiring substrate according to the first aspect of the present invention, a via conductor electrically connected to a side of the coating conductor that is opposite from the through hole conductor, and may be disposed so that at least a portion of a surface of the via conductor that comes into contact with the coating conductor faces the opening on one end side of the through hole.

In the multilayer wiring substrate having such a configuration, since the distance between the via conductor and the opening on one end side shortens, a fine wiring pattern can be formed within the first build-up layer.

In addition, in the multilayer wiring substrate according to the first aspect of the present invention, the center of the surface of the via conductor which comes into contact with the coating conductor may coincide with a center of the opening on one end side.

In the multilayer wiring substrate having such a configuration, it is possible to shorten an electrical current path reaching from the through hole conductor to the via conductor, and to reduce electrical resistance between the via conductor and the through hole conductor.

In addition, according to a second aspect of the present invention, there is provided a method of manufacturing a multilayer wiring substrate including a first build-up layer and a second build-up layer which are formed by laminating at least one insulating layer and at least one conductor layer, and a supporting substrate that supports the first build-up layer and the second build-up layer on an upper surface and a lower surface thereof, respectively, the method including: a first process of forming a through hole on a substrate that includes a supporting substrate insulating layer constituting the supporting substrate, a first conductor layer formed throughout the entirety of an upper surface of the supporting substrate insulating layer, and a second conductor layer formed throughout the entirety of a lower surface of the supporting substrate insulating layer, the through hole extending between the upper surface of the supporting substrate insulating layer and the lower surface thereof by passing through the second conductor layer and reaching the first conductor layer without passing through the first conductor layer; a second process of forming a through hole conductor, which electrically connects the first conductor layer and the second conductor layer, on an inner circumferential surface of the through hole; a third process of patterning the first conductor layer and the second conductor layer so that a wiring pattern which is set in advance is formed, after the through hole conductor is formed through the second process; and a fourth process of laminating an insulating layer on the supporting substrate insulating layer after the wiring pattern is formed through the third process, and filling an inner side of the through hole conductor and the through hole formed in the second conductor layer with a portion of the insulating layer.

The manufacturing method is a method of manufacturing a multilayer wiring substrate according to the aspect of the present invention, and the method is performed, thereby allowing the same effect as that of the multilayer wiring substrate according to the aspect of the present invention to be obtained.

In addition, according to a third aspect of the present invention, there is provided a method of manufacturing a multilayer wiring substrate, including: a process of forming, on a base substrate, an underlying laminate in which at least one insulating layer and at least one conductor layer are alternately laminated along a lamination direction which is set in advance; a process of laminating an intermediate insulating layer on a third conductor layer constituting an outermost layer of the underlying laminate, and further laminating a fourth conductor layer on the intermediate insulating layer; a process of forming a through hole which extends through the intermediate insulating layer in the lamination direction by passing through the fourth conductor layer and reaches the third conductor layer without passing through the third conductor layer; a process of forming a through hole conductor that electrically connects the third conductor layer and the fourth conductor layer, on an inner circumferential surface of the through hole; a process of patterning the fourth conductor layer so that a wiring pattern which is set in advance is formed, after the through hole conductor is formed; and a process of laminating an insulating layer on the intermediate insulating layer after the wiring pattern is formed, and filling an inner side of the through hole conductor and the through hole formed in the fourth conductor layer with a portion of the insulating layer.

In the manufacturing method according to the third aspect of the present invention having such a configuration, the insulating layer is laminated on the intermediate insulating layer, whereby inside the through hole can be embedded the insulating layer. Thereby, it is possible to eliminate the need for a special process for embedding inside the through hole.

In addition, the through hole is formed so as to reach the third conductor layer without passing through the intermediate conductor layer. That is, when the opening on one end side of the through hole is set to an opening on the third conductor layer side, and the opening on the other end side of the through hole is set to an opening on the fourth conductor layer side, the opening on the third conductor layer side in the through hole is covered by the third conductor layer. For this reason, the via conductor formed on the third conductor layer at the side opposite from the through hole with the third conductor layer interposed therebetween can be disposed directly above the opening on the third conductor layer side in the through hole through the third conductor layer.

In addition, according to a fourth aspect of the present invention, there is provided a method of manufacturing a multilayer wiring substrate, including: a process of forming, on a base substrate, an underlying laminate in which at least one insulating layer and at least one conductor layer are alternately laminated along a lamination direction which is set in advance; a process of laminating an intermediate insulating layer on a third conductor layer constituting an outermost layer of the underlying laminate; a process of forming a through hole which extends through the intermediate insulating layer in the lamination direction and reaches the third conductor layer without passing through the third conductor layer; a process of laminating a metal layer on the intermediate insulating layer and on an inner circumferential surface of the through hole to form a fourth conductor layer on the intermediate insulating layer and form a through hole conductor on the inner circumferential surface of the through hole; a process of patterning the fourth conductor layer so that a wiring pattern which is set in advance is formed, after the through hole conductor is formed; and a process of laminating an insulating layer on the intermediate insulating layer after the wiring pattern is formed, and filling an inner side of the through hole conductor with a portion of the insulating layer.

In the manufacturing method according to the fourth aspect of the present invention having such a configuration, the insulating layer is laminated on the intermediate insulating layer, whereby inside the through hole can be embedded the insulating layer. Thereby, it is possible to eliminate the need for a special process for embedding inside the through hole.

In addition, the through hole is formed so as to reach the third conductor layer without passing through the third conductor layer. That is, when the opening on one end side of the through hole is set to an opening on the third conductor layer side, and the opening on the other end side of the through hole is set to an opening on the fourth conductor layer side, the opening on the third conductor layer side in the through hole is covered by the third conductor layer. For this reason, the via conductor, which is formed on the third conductor layer at the side opposite from the through hole so that the third conductor layer is interposed therebetween, can be disposed directly above the opening on the third conductor layer side in the through hole through the third conductor layer.

### BRIEF DESCRIPTION OF THE DRAWINGS

FIG. 1 is a cross-sectional view illustrating a schematic configuration of a multilayer wiring substrate 1.

FIG. 2 is a first cross-sectional view illustrating a process of manufacturing the multilayer wiring substrate 1.

FIG. 3 is a second cross-sectional view illustrating a process of manufacturing the multilayer wiring substrate 1.

FIG. 4 is a third cross-sectional view illustrating a process of manufacturing the multilayer wiring substrate 1.

FIG. 5 is a fourth cross-sectional view illustrating a process of manufacturing the multilayer wiring substrate 1.

FIG. 6 is a fifth cross-sectional view illustrating a process of manufacturing the multilayer wiring substrate 1.

FIG. 7 is a sixth cross-sectional view illustrating a process of manufacturing the multilayer wiring substrate 1.

FIG. 8 is a seventh cross-sectional view illustrating a process of manufacturing the multilayer wiring substrate 1.

FIG. 9 is a cross-sectional view illustrating a schematic configuration of a multilayer wiring substrate 101.

FIG. 10 is a first cross-sectional view illustrating a process of manufacturing the multilayer wiring substrate 101.

FIG. 11 is a second cross-sectional view illustrating a process of manufacturing the multilayer wiring substrate 101.

FIG. 12 is a third cross-sectional view illustrating a process of manufacturing the multilayer wiring substrate 101.

FIG. 13 is a fourth cross-sectional view illustrating a process of manufacturing the multilayer wiring substrate 101.

FIG. 14 is a fifth cross-sectional view illustrating a process of manufacturing the multilayer wiring substrate 101.

FIG. 15 is a sixth cross-sectional view illustrating a process of manufacturing the multilayer wiring substrate 101.

FIG. 16 is a seventh cross-sectional view illustrating a process of manufacturing the multilayer wiring substrate 101.

FIG. 17 is an eighth cross-sectional view illustrating a process of manufacturing the multilayer wiring substrate 101.

FIG. 18 is a ninth cross-sectional view illustrating a process of manufacturing the multilayer wiring substrate 101.

FIG. 19 is a cross-sectional view illustrating a schematic configuration of a multilayer wiring substrate 501.

FIG. 20 is a first cross-sectional view illustrating a process of manufacturing the multilayer wiring substrate 501 of a third embodiment.

FIG. 21 is a second cross-sectional view illustrating a process of manufacturing the multilayer wiring substrate 501 of the third embodiment.

FIG. 22 is a third cross-sectional view illustrating a process of manufacturing the multilayer wiring substrate 501 of the third embodiment.

FIG. 23 is a fourth cross-sectional view illustrating a process of manufacturing the multilayer wiring substrate 501 of the third embodiment.

FIG. 24 is a fifth cross-sectional view illustrating a process of manufacturing the multilayer wiring substrate 501 of the third embodiment.

FIG. 25 is a sixth cross-sectional view illustrating a process of manufacturing the multilayer wiring substrate 501 of the third embodiment.

FIG. 26 is a seventh cross-sectional view illustrating a process of manufacturing the multilayer wiring substrate 501 of the third embodiment.

### DETAILED DESCRIPTION OF EXEMPLARY EMBODIMENTS OF THE INVENTION

### First Embodiment

Hereinafter, a first embodiment of the present invention will next be described with reference to the drawings.

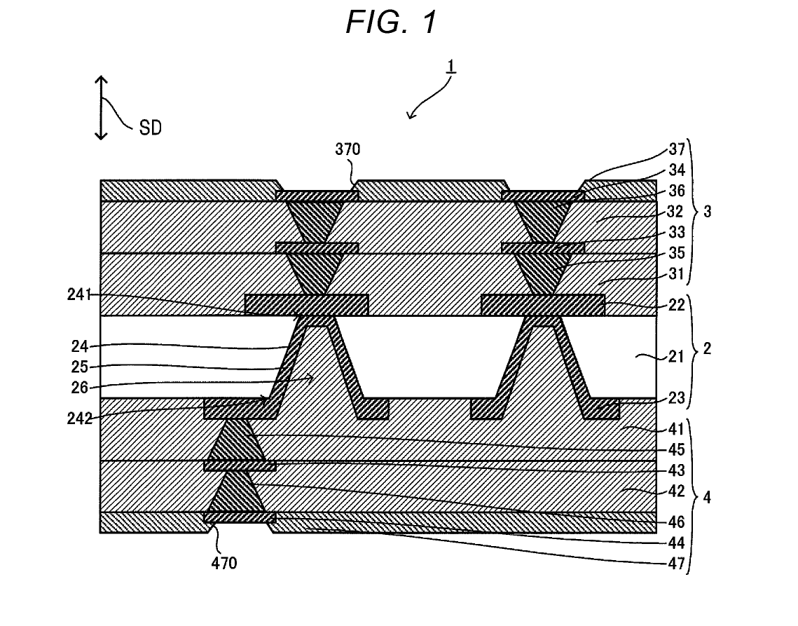

As shown in FIG. 1, a multilayer wiring substrate 1 of a first embodiment to which the invention is applied includes a supporting layer 2 and build-up layers 3 and 4, and is configured such that the build-up layer 3 and the build-up layer 4 are laminated on the upper surface and the lower surface of the supporting layer 2, respectively, along the lamination direction SD.

First, the supporting layer 2 includes a supporting substrate 21 and conductor layers 22 and 23. The supporting substrate 21 is, for example, a plate-like member obtained by impregnating a glass fiber with an epoxy resin, and has a high rigidity. The conductor layer 22 and the conductor layer 23 are laminated on the upper surface and the lower surface of the supporting substrate 21, respectively. In addition, a through hole 24 passing through the supporting substrate 21 is formed within the supporting substrate 21. A through hole conductor 25 is formed on the inner circumferential surface of the through hole 24. Meanwhile, the through hole 24 is formed in a truncated cone shape, and an opening 242 on the lower surface side (lower end side of the through hole) is larger in diameter than an opening 241 on the upper surface side (upper end side of the through hole).

In addition, the conductor layer 22 is formed so as to cover the opening 241 on the upper surface side of the through hole 24. Meanwhile, the through hole conductor 25 is formed so as to cover not only the inner circumferential surface of the through hole 24 but also the opening 241 of the through hole 24. For this reason, the conductor layer 22 comes into contact with the through hole conductor 25 in the entire region of the opening 241, and thereby the conductor layer 22 and the through hole conductor 25 are electrically connected to each other.

In addition, the conductor layer 23 is formed in the periphery of the opening 242 so as not to cover the opening 242 on the lower surface side of the through hole 24. For this reason, the conductor layer 23 comes into contact with the through hole conductor 25 along the opening end edge of the opening 242, and thereby the conductor layer 23 and the through hole conductor 25 are electrically connected to each other. In addition, an insulating layer 41 (described later) constituting the build-up layer 4 is embedded in a bottomed hole 26 which is formed further inside than the inner circumferential side of the through hole conductor 25 formed on the inner circumferential surface of the through hole 24.

The build-up layer 3 includes insulating layers 31 and 32, conductor layers 33 and 34, via conductors 35 and 36, and a solder resist layer 37. In addition, the build-up layer 3 is configured such that the insulating layers 31 and 32 and the conductor layers 33 and 34 are alternately laminated along the lamination direction SD.

The via conductors 35 and 36 are respectively formed within the insulating layers 31 and 32 so as to extend in the lamination direction SD. Thereby, the conductor layer 33 is electrically connected to the conductor layer 22, and the conductor layer 34 is electrically connected to the conductor layer 33. Meanwhile, the via conductors 35 and 36 are formed in a truncated cone shape, and the upper surface and the lower surface thereof are circular. At least a portion of a plurality of via conductors 35 and 36 is disposed so that the center of the lower surface thereof and the center of opening 241 on the upper surface side of the through hole 24 face each other along the lamination direction SD.

In addition, the build-up layer 4 includes insulating layers 41 and 42, conductor layers 43 and 44, via conductors 45 and 46, and a solder resist layer 47. In addition, the build-up layer 4 is configured such that the insulating layers 41 and 42 and the conductor layers 43 and 44 are alternately laminated along the lamination direction SD. The via conductors 45 and 46 are respectively formed within the insulating layers 41 and 42 so as to extend in the lamination direction SD. Thereby, the conductor layer 43 is electrically connected to the conductor layer 23, and the conductor layer 44 is electrically connected to the conductor layer 43. In addition, the solder resist layer 47 is laminated on the insulating layer 42, and an opening 470 is formed in a region in which the conductor layer 44 is disposed.

Next, a method of manufacturing the multilayer wiring substrate 1 to which the invention is applied will be described.

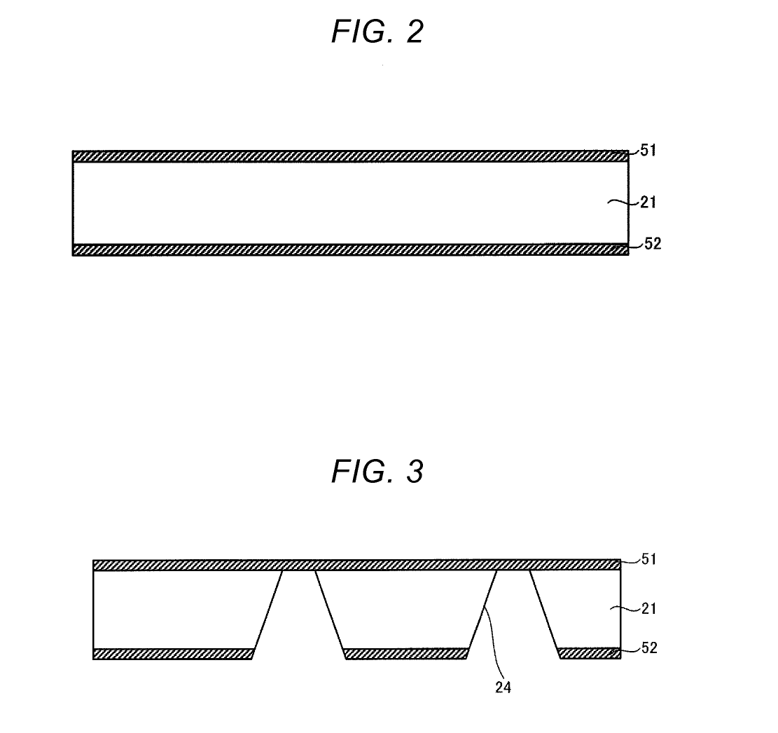

As shown in FIG. 2, first, the supporting substrate 21 having a conductor layer 51 and a conductor layer 52 (copper in the present embodiment) laminated on the upper surface and the lower surface thereof, respectively, is prepared. A predetermined position on the surface of the conductor layer 52 is then irradiated with a laser beam, so that the through hole 24 passing through the conductor layer 52 and the supporting substrate 21 is formed as shown in FIG. 3.

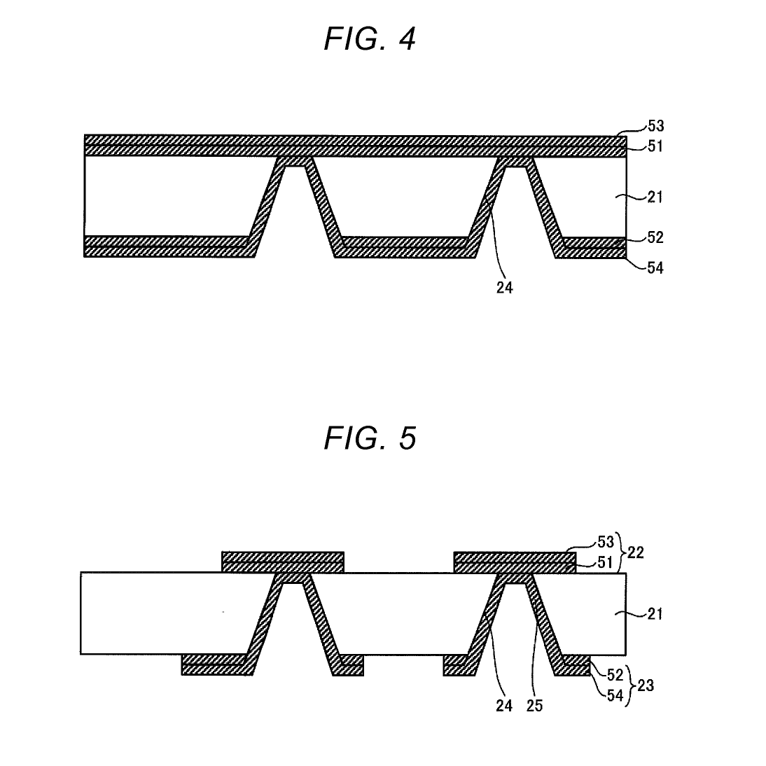

Further, a process (desmear process) for removing a smear generated within the through hole 24 by the formation of the through hole 24 is performed. Thereafter, electroless plating and electroplating are performed. Thereby, as shown in FIG. 4, a plating layer 53 (copper in the present embodiment) is formed on the conductor layer 51, and a plating layer 54 (copper in the present embodiment) is formed on the inner circumferential surface of the through hole 24 and on the conductor layer 52. Thereafter, the conductor layers 51 and 52 and the plating layers 53 and 54, which are unnecessary, are removed using a subtractive process, so that the conductor layers 22 and 23 having a predetermined wiring pattern are formed as shown in FIG. 5. Therefore, the conductor layer 51 and the plating layer 53 laminated so as to have a predetermined wiring pattern are equivalent to the conductor layer 22. In addition, the conductor layer 52 and the plating layer 54 laminated so as to have a predetermined wiring pattern are equivalent to the conductor layer 23. In addition, the plating layer 54 formed on the inner circumferential surface of the through hole 24 is equivalent to the through hole conductor 25.

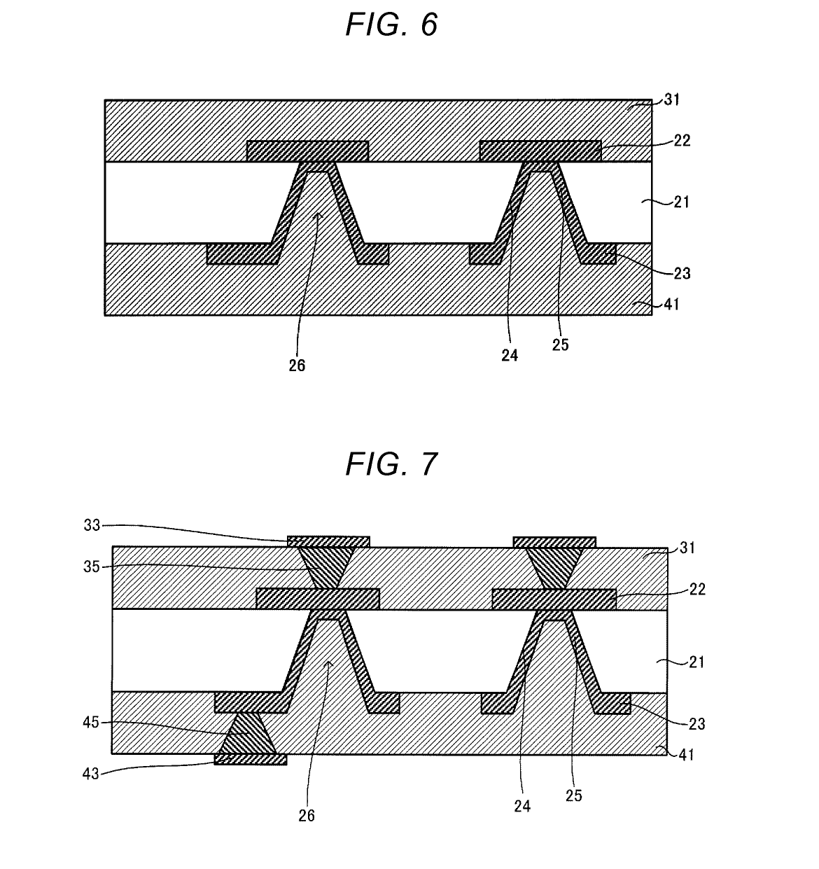

Thereafter, a film-shaped resin material (for example, epoxy resin) is disposed on the supporting substrate 21 with respect to each of both sides of the supporting substrate 21, and the resin material is cured by pressurization and heating under vacuum, so that the insulating layers 31 and 41 are formed. Thereby, as shown in FIG. 6, the upper surface of the supporting substrate 21 and the conductor layer 22 are coated with the insulating layer 31. In addition, the lower surface of the supporting substrate 21 and the conductor layer 23 are coated with the insulating layer 41, and thus the insulating layer 41 is embedded in the bottomed hole 26.

Predetermined positions on the surfaces of the insulating layers 31 and 41 are then irradiated with a laser beam, so that a plurality of via holes are formed within the insulating layers 31 and 41. Further, a process (desmear process) for removing a smear generated within the via holes by the formation of the via holes is performed. Thereafter, electroless plating is performed, so that a thin electroless plating layer (copper in the present embodiment) is formed on the insulating layers 31 and 41. A predetermined resist pattern corresponding to a wiring pattern of the conductor layers 33 and 43 is then formed on the electroless plating layer. Further, electroplating is performed, so that a plating layer (copper in the present embodiment) is formed on a region which is not covered with a resist. Thereafter, the electroless plating layer and the resist which are unnecessary are removed by etching. Thereby, as shown in FIG. 7, the via conductors 35 and 45 are formed within the via holes, and the conductor layers 33 and 43 having a predetermined wiring pattern are formed.

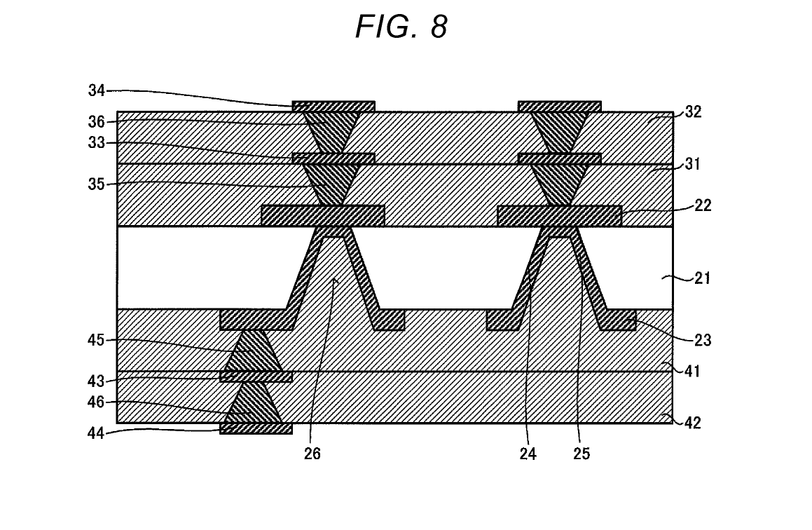

Further, using the same process as that of forming the insulating layers 31 and 41, the conductor layers 33 and 43, and the via conductors 35 and 45, as shown in FIG. 8, the insulating layers 32 and 42, the conductor layers 34 and 44, and the via conductors 36 and 46 are formed on the insulating layers 31 and 41.

After a solder resist made of an organic resin material such as an epoxy resin is applied so as to cover the insulating layers 32 and 42 and the conductor layers 34 and 44, the solder resist is patterned. Thereby, as shown in FIG. 1, the solder resist layers 37 and 47 having openings 370 and 470 in regions on which the conductor layers 34 and 44 are disposed are formed on the insulating layers 32 and 42.

In the multilayer wiring substrate 1 having such a configuration, since the through hole 24 which extends in the direction between the upper surface of the supporting substrate 21 and the lower surface thereof and passes through the supporting substrate, and the through hole conductor 25 is formed on the inner circumferential surface of the through hole 24, the upper surface and the lower surface of the supporting substrate 21 can be electrically connected to each other through the through hole conductor 25.

The conductor layer 22 formed so as to cover the opening 241 on the upper surface side of the through hole 24 and the conductor layer 23 formed in the periphery of the opening 242 without covering the opening 242 on the lower surface side of the through hole 24 are electrically connected to the through hole conductor 25. That is, the conductor layer 22 disposed on the upper surface of the supporting substrate 21 is electrically connected to the conductor layer 23 disposed on the lower surface of the supporting substrate 21. For this reason, the build-up layer 3 formed on the upper surface of the supporting substrate 21 and the build-up layer 4 formed on the lower surface of the supporting substrate 21 can be electrically connected to each other through the conductor layer 22 and the conductor layer 23.

In addition, the conductor layer 22 is formed so as to cover the opening 241 on the upper surface side of the through hole 24. For this reason, the via conductor 35 which is formed within the insulating layer 31 of the build-up layer 3 in order to electrically connect the conductor layer 33 located within the build-up layer 3 and the conductor layer 22 to each other can be disposed directly above the opening 241 on the upper surface side of the through hole 24 through the conductor layer 22. Thereby, a fine wiring pattern can be formed in the conductor layer 33 of the build-up layer 3.

Further, the conductor layer 23 is formed in the periphery of the opening 242 without covering the opening 242 on the lower surface side of the through hole 24. For this reason, in a process of laminating the insulating layer 41 constituting the build-up layer 4 on the lower surface of the supporting substrate 21, inside the through hole 24 can be embedded the insulating layer 41 laminated on the lower surface of the supporting substrate 21. Thereby, it is possible to eliminate the need for a special process for embedding inside the through hole 24.

In addition, in the multilayer wiring substrate 1, the via conductor 35 is disposed so that at least a portion of the surface that comes into contact with the conductor layer 22 faces the opening 241 on the upper surface side of the through hole 24. Thereby, since the distance between the via conductor 35 and the opening 241 shortens, a fine wiring pattern can be formed within the build-up layer 3.

In addition, in the multilayer wiring substrate 1, the via conductor 35 is disposed so that the center of the surface that comes into contact with the conductor layer 22 coincides with the center of the opening 241 on the upper surface side of the through hole 24. Thereby, it is possible to shorten an electrical current path reaching from the through hole conductor 25 to the via conductor 35, and to reduce electrical resistance between the via conductor 35 and the through hole conductor 25.

In the embodiment described above, the build-up layer 3 is a first build-up layer in the invention, the build-up layer 4 is a second build-up layer in the invention, the opening 241 is an opening on one end side in the invention, the conductor layer 22 is a coating conductor in the invention, the opening 242 is an opening on the other end side in the invention, the conductor layer 23 is a non-coating conductor in the invention, and the via conductor 35 is a via conductor in the invention.

In addition, the supporting substrate 21 is a supporting substrate insulating layer in the invention, the conductor layer 51 is a first conductor layer in the invention, and the conductor layer 52 is a second conductor layer in the invention.

### Second Embodiment

Hereinafter, a second embodiment of the invention will be described with reference to the accompanying drawings.

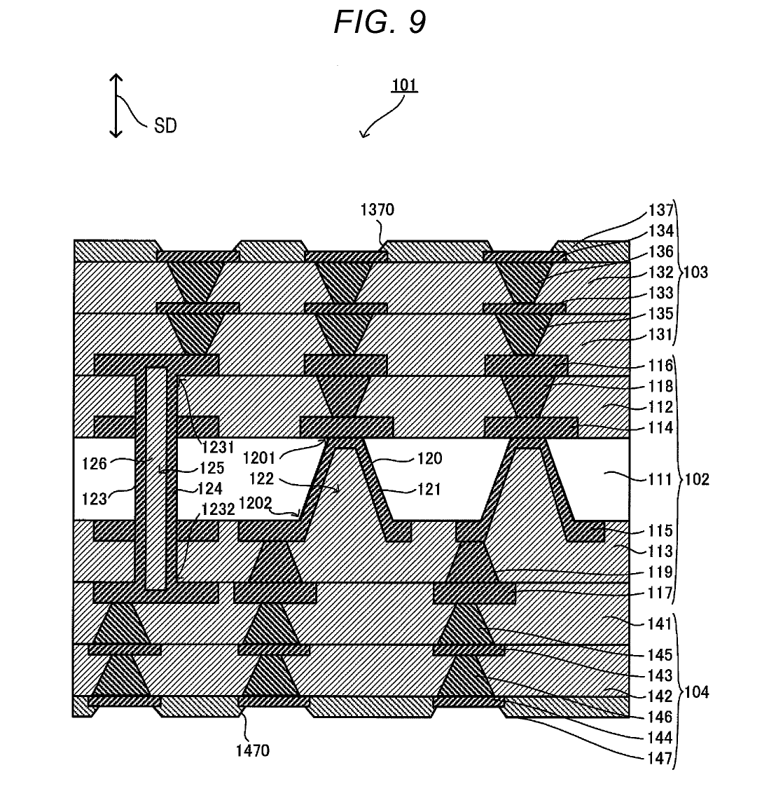

As shown in FIG. 9, a multilayer wiring substrate 101 of a second embodiment to which the invention is applied includes a supporting layer 102 and build-up layers 103 and 104, and is configured such that a build-up layer 103 and a build-up layer 104 are laminated on the upper surface and the lower surface of the supporting layer 102, respectively, along the lamination direction SD.

First of all, the supporting layer 102 includes a supporting substrate 111, insulating layers 112 and 113, conductor layers 114, 115, 116, and 117, and via conductors 118 and 119. The supporting substrate 111 is, for example, a plate-like member obtained by impregnating a glass fiber with an epoxy resin, and has a high rigidity.

The conductor layer 114 and the conductor layer 115 are laminated on the upper surface and the lower surface of the supporting substrate 111, respectively. In addition, the insulating layers 112 and 113 are laminated on the conductor layers 114 and 115, respectively. Further, the conductor layers 116 and 117 are laminated on the insulating layers 112 and 113, respectively.

In addition, a through hole 120 passing through the supporting substrate 111 is formed within the supporting substrate 111. A through hole conductor 121 is formed on the inner circumferential surface of the through hole 120. Meanwhile, the through hole 120 is formed in a truncated cone shape, and an opening 1202 on the lower surface side is larger in diameter than an opening 1201 on the upper surface side.

The conductor layer 114 is formed on the opening 1201 on the upper surface side of the through hole 120 so as to cover the opening 1201. Meanwhile, the through hole conductor 121 is formed so as to cover not only the inner circumferential surface of the through hole 120 but also the opening 1201 of the through hole 120. For this reason, the conductor layer 114 comes into contact with the through hole conductor 121 in the entire region of the opening 1201, and thereby the conductor layer 114 and the through hole conductor 121 are electrically connected to each other.

In addition, in the opening 1202 on the lower surface side of the through hole 120, the conductor layer 115 is formed in the periphery of the opening 1202 so as not to cover the opening 1202. For this reason, the conductor layer 115 comes into contact with the through hole conductor 121 along the opening end edge of the opening 1202, and thereby the conductor layer 115 and the through hole conductor 121 are electrically connected to each other. In addition, the insulating layer 113 is embedded in a bottomed hole 122 which is formed further inside than the inner circumferential side of the through hole conductor 121 formed on the inner circumferential surface of the through hole 120.

The via conductors 118 and 119 are respectively formed within the insulating layers 112 and 113 so as to extend in the lamination direction SD. Thereby, the conductor layer 114 is electrically connected to the conductor layer 116, and the conductor layer 115 is electrically connected to the conductor layer 117. Meanwhile, the via conductors 118 and 119 are formed in a truncated cone shape, and the upper surface and the lower surface thereof are circular. At least a portion of a plurality of via conductors 118 is disposed so that the center of the lower surface thereof and the center of the opening 1201 on the upper surface side of the through hole 120 face each other in the lamination direction SD.

In addition, a through hole 123 passing through the supporting substrate 111 and the insulating layers 112 and 113 is formed within the supporting layer 102. A through hole conductor 124 is formed on the inner circumferential surface of the through hole 123. Meanwhile, the through hole 123 is formed in a cylindrical shape, and the diameters of an opening 1231 on the upper surface side and an opening 1232 on the lower surface side are equal to each other. In addition, a resin 126 containing an inorganic filler is embedded in the through hole 124 which is formed further inside than the inner circumferential side of the through hole conductor 124 formed on the inner circumferential surface of the through hole 123.

The conductor layer 116 is formed on the opening 1231 on the upper surface side of the through hole 123 so as to cover the opening 1231. In addition, the conductor layer 117 is formed on the opening 1232 on the lower surface side of the through hole 123 so as to cover the opening 1232. For this reason, the conductor layers 116 and 117 come into contact with the through hole conductor 124 along the opening end edges of the openings 1231 and 1232, respectively, and thereby the conductor layers 116 and 117 and the through hole conductor 124 are electrically connected to each other.

Next, the build-up layer 103 includes insulating layers 131 and 132, conductor layers 133 and 134, via conductors 135 and 136, and a solder resist layer 137. In addition, the build-up layer 103 is configured such that the insulating layers 131 and 132 and the conductor layers 133 and 134 are alternately laminated along the lamination direction SD. The via conductors 135 and 136 are respectively formed within the insulating layers 131 and 132 so as to extend in the lamination direction SD. Thereby, the conductor layer 133 is electrically connected to the conductor layer 116, and the conductor layer 134 is electrically connected to the conductor layer 133. In addition, the solder resist layer 137 is laminated on the insulating layer 132, and an opening 1370 is formed in a region on which the conductor layer 134 is disposed.

In addition, the build-up layer 104 includes insulating layers 141 and 142, conductor layers 143 and 144, via conductors 145 and 146, and a solder resist layer 147. In addition, the build-up layer 104 is configured such that the insulating layers 141 and 142 and the conductor layers 143 and 144 are alternately laminated along the lamination direction SD. The via conductors 145 and 146 are respectively formed within the insulating layers 141 and 142 so as to extend in the lamination direction SD. Thereby, the conductor layer 143 is electrically connected to the conductor layer 117, and the conductor layer 144 is electrically connected to the conductor layer 143. In addition, the solder resist layer 147 is laminated on the insulating layer 142, and an opening 1470 is formed in a region on which the conductor layer 144 is disposed.

Next, a method of manufacturing the multilayer wiring substrate 101 to which the invention is applied will be described.

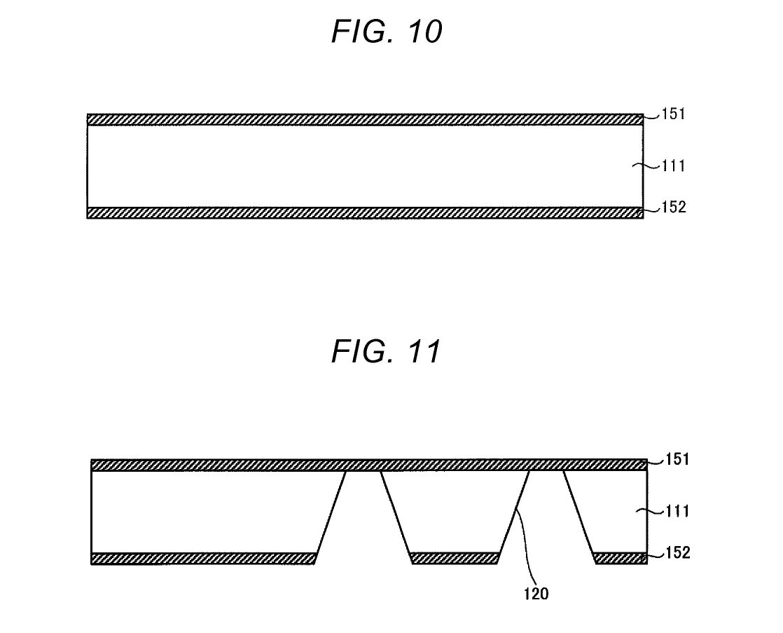

As shown in FIG. 10, first, the supporting substrate 111 having a conductor layer 151 and a conductor layer 152 (copper in the present embodiment) laminated on the upper surface and the lower surface thereof, respectively, is prepared. A predetermined position on the surface of the conductor layer 152 is then irradiated with a laser beam, so that the through hole 120 passing through the conductor layer 152 and the supporting substrate 111 is formed as shown in FIG. 11.

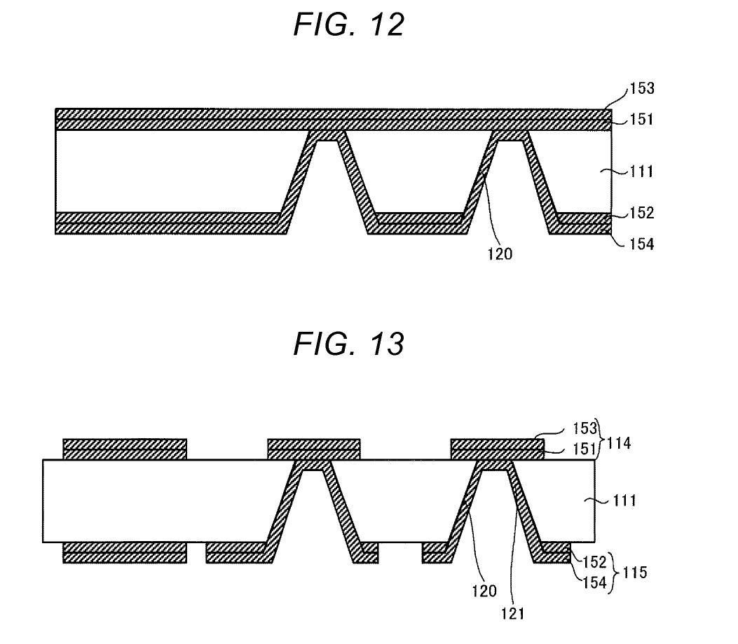

Further, a process (desmear process) for removing a smear generated within the through hole 120 by the formation of the through hole 120 is performed. Thereafter, electroless plating and electroplating are performed. Thereby, as shown in FIG. 12, a plating layer 153 (copper in the present embodiment) is formed on the conductor layer 151, and a plating layer 154 (copper in the present embodiment) is formed on the inner circumferential surface of the through hole 120 and on the conductor layer 152. Thereafter, the conductor layers 151 and 152 and the plating layers 153 and 154, which are unnecessary, are removed using a subtractive process, so that the conductor layers 114 and 115 having a predetermined wiring pattern are formed as shown in FIG. 13. Therefore, the conductor layer 151 and the plating layer 153 laminated so as to have a predetermined wiring pattern are equivalent to the conductor layer 114. In addition, the conductor layer 152 and the plating layer 154 laminated so as to have a predetermined wiring pattern is equivalent to the conductor layer 115. In addition, the plating layer 154 formed on the inner circumferential surface of the through hole 120 is equivalent to the through hole conductor 121.

Thereafter, a film-shaped resin material (for example, epoxy resin) is disposed on the supporting substrate 111 with respect to each of both sides of the supporting substrate 111, and the resin material is cured by pressurization and heating under vacuum, so that the insulating layers 112 and 113 are formed. Thereby, the upper surface of the supporting substrate 111 and the conductor layer 114 are coated with the insulating layer 112. In addition, the lower surface of the supporting substrate 111 and the conductor layer 115 are coated with the insulating layer 113, and thus the insulating layer 113 is embedded in the bottomed hole 122.

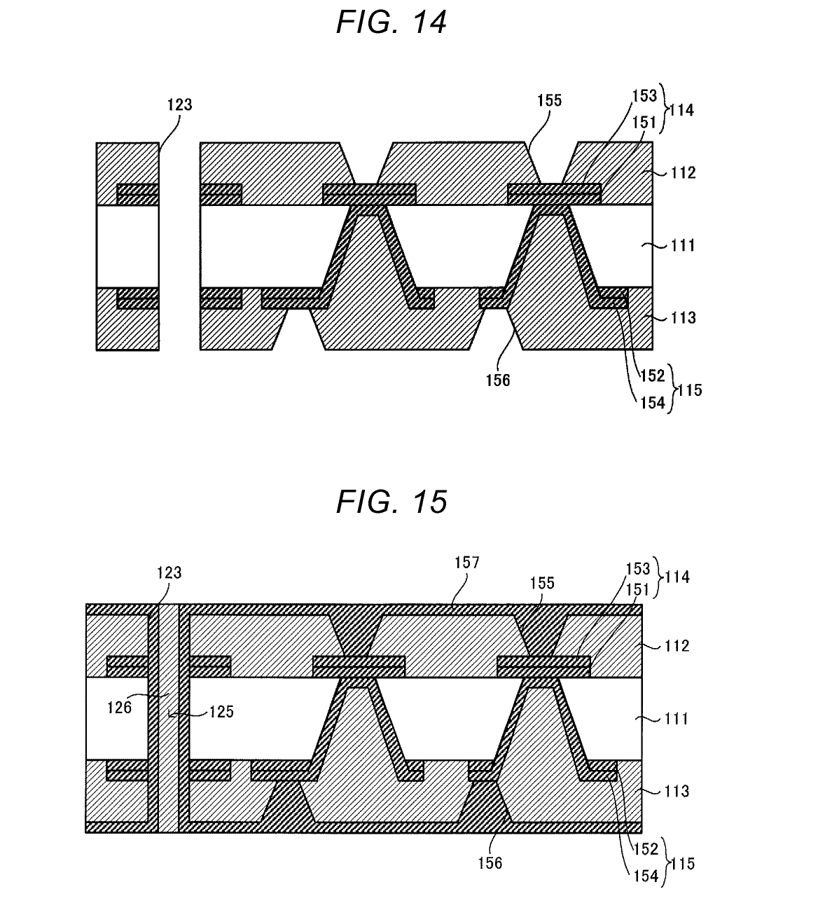

Predetermined positions on the surfaces of the insulating layers 112 and 113 are then irradiated with a laser beam, so that a plurality of via holes 155 and 156 are formed within the insulating layers 112 and 113 as shown in FIG. 14. Further, a process (desmear process) for removing a smear generated within the via holes 155 and 156 by the formation of the via holes 155 and 156 is performed. Thereafter, a spot located at a predetermined position on the surface of the insulating layer 112 is punched by a drill, so that the through hole 123 passing through the supporting substrate 111 and the insulating layers 112 and 113 are formed.

Thereafter, electroless plating is performed, so that a thin electroless plating layer (copper in the present embodiment) is formed on the insulating layers 112 and 113 and on the inner circumferential surface of the through hole 123. Further, electroplating is performed, so that a plating layer 157 (copper in the present embodiment) is formed, as shown in FIG. 15, on the insulating layers 112 and 113, within the via holes 155 and 156, and on the inner circumferential surface of the through hole 123. A paste of the resin 126 containing an inorganic filler is filled in a through hole 125 which is formed further inside than the inner circumferential side of the plating layer 157 formed on the inner circumferential surface of the through hole 123, and the paste is thermally cured. Thereby, the resin 126 is embedded in the through hole 125.

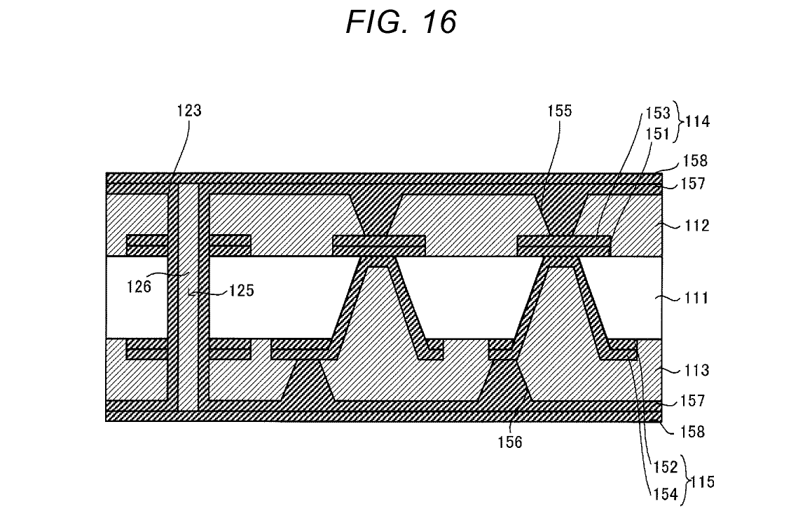

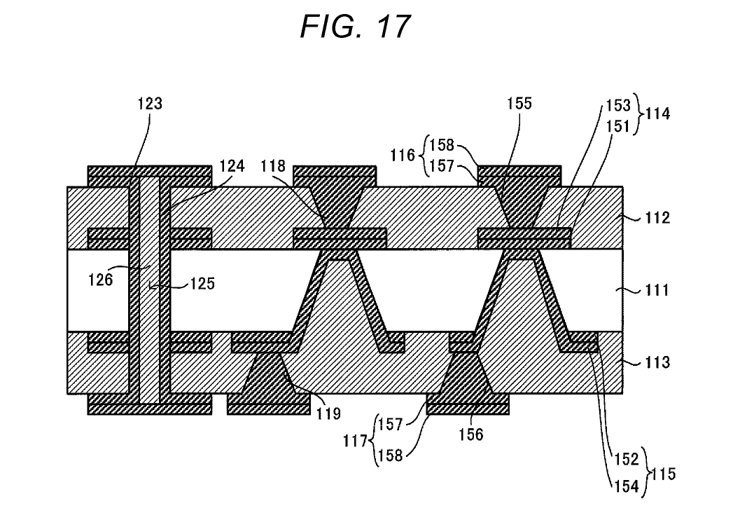

Next, electroplating is performed, so that a plating layer 158 (copper in the present embodiment) is further formed on the plating layer 157 as shown in FIG. 16. Thereafter, the plating layers 157 and 158 which are unnecessary are removed using a subtractive process, so that the conductor layers 116 and 117 having a predetermined wiring pattern are formed as shown in FIG. 17.

Therefore, the plating layers 157 and 158 laminated so as to have a predetermined wiring pattern on the insulating layer 112 are equivalent to the conductor layer 116. In addition, the plating layers 157 and 158 laminated so as to have a predetermined wiring pattern on the insulating layer 113 are equivalent to the conductor layer 117. In addition, the plating layer 157 embedded in the via holes 155 and 156 is equivalent to the via conductors 118 and 119. In addition, the plating layer 157 formed on the inner circumferential surface of the through hole 123 is equivalent to the through hole conductor 124.

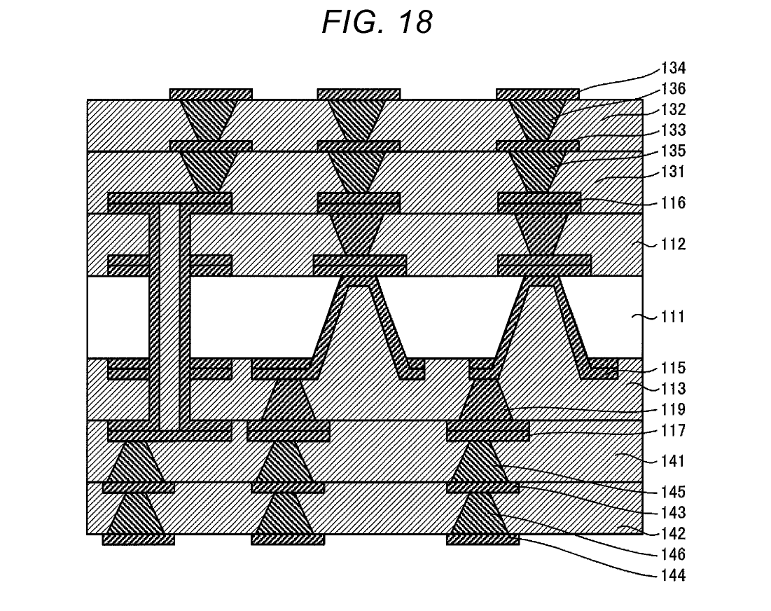

Thereafter, a film-shaped resin material (for example epoxy resin) is disposed on the insulating layers 112 and 113, and the resin material is cured by pressurization and heating under vacuum, so that the insulating layers 131 and 141 are formed as shown in FIG. 18. Thereby, the insulating layers 112 and 113 and the conductor layers 116 and 117 are coated with the insulating layers 131 and 141.

Predetermined positions on the surfaces of the insulating layers 131 and 141 are then irradiated with a laser beam, so that a plurality of via holes are formed within the insulating layers 131 and 141. Further, a process (desmear process) for removing a smear generated within the via holes by the formation of the via holes is performed. Thereafter, electroless plating is performed, so that a thin electroless plating layer (copper in the present embodiment) is formed on the insulating layers 131 and 141. A predetermined resist pattern corresponding to a wiring pattern of the conductor layers 133 and 143 is formed on the electroless plating layer. Further, electroplating is performed, so that a plating layer (copper in the present embodiment) is formed on a region which is not covered with a resist. Thereafter, the electroless plating layer and the resist which are unnecessary are removed by etching. Thereby, the via conductors 135 and 145 are formed within the via holes, and the conductor layers 133 and 143 having a predetermined wiring pattern are formed.

Further, using the same process as that of forming the insulating layers 131 and 141, the conductor layers 133 and 143, and the via conductors 135 and 145, the insulating layers 132 and 142, the conductor layers 134 and 144, and the via conductors 136 and 146 are formed on the insulating layers 131 and 141.

After, a solder resist made of an organic resin material such as an epoxy resin is applied so as to cover the insulating layers 132 and 142 and the conductor layers 134 and 144, the solder resist is patterned. Thereby, as shown in FIG. 9, the solder resist layers 137 and 147 having the openings 1370 and 1470 in regions on which the conductor layers 134 and 144 are disposed are formed on the insulating layers 132 and 142.

In the multilayer wiring substrate 101 having such a configuration, since the through hole 120 which extends between the upper surface side of the supporting layer 102 and the lower surface side thereof is formed, and the through hole conductor 121 is formed on the inner circumferential surface of the through hole 120, the upper surface side and the lower surface side of the supporting layer 102 can be electrically connected to each other through the through hole conductor 121.

The conductor layer 114 formed so as to cover the opening 1201 on the upper surface side of the through hole 120 and the conductor layer 115 formed in the periphery of the opening 1202 without covering the opening 1202 on the lower surface side of the through hole 120 are electrically connected to the through hole conductor 121. That is, the conductor layer 114 disposed on the upper surface of the supporting substrate 111 is electrically connected to the conductor layer 115 disposed on the lower surface of the supporting substrate 111. For this reason, the build-up layer 103 formed on the upper surface of the supporting layer 102 and the build-up layer 104 formed on the lower surface of the supporting layer 102 can be electrically connected to each other through the conductor layers 114 and 115 and the via conductors 118 and 119 formed on the conductor layers 114 and 115.

In addition, the conductor layer 114 is formed so as to cover the opening 1201 on the upper surface side of the through hole 120. For this reason, since the conductor layer 116 and the conductor layer 114 of the supporting layer 102 are electrically connected to each other, the via conductor 118 formed within the insulating layer 112 of the supporting layer 102 can be disposed directly on the opening 1201 on the upper surface side of the through hole 120 through the conductor layer 114. Thereby, a fine wiring pattern can be formed in the conductor layer 116 of the supporting layer 102.

Further, the conductor layer 115 is formed in the periphery of the opening 1202 without covering the opening 1202 on the lower surface side of the through hole 120. For this reason, in a process of laminating the insulating layer 113 on the lower surface of the supporting substrate 111, inside the through hole 120 can be embedded the insulating layer 113 laminated on the lower surface of the supporting substrate 111. Thereby, it is possible to eliminate the need for a special process for embedding inside the through hole 120.

In the embodiment described above, the build-up layer 103 is a first build-up layer in the invention, the build-up layer 104 is a second build-up layer in the invention, the supporting layer 102 is a supporting substrate in the invention, the opening 1201 is an opening on one end side in the invention, the conductor layer 114 is a coating conductor in the invention, the opening 1202 is an opening on the other end side in the invention, and the conductor layer 115 is a non-coating conductor in the invention.

In addition, the supporting substrate 111 is a supporting substrate insulating layer in the invention, the conductor layer 151 is a first conductor layer in the invention, and the conductor layer 152 is a second conductor layer in the invention.

### Third Embodiment

Hereinafter, a third embodiment of the invention will be described with reference to the accompanying drawings.

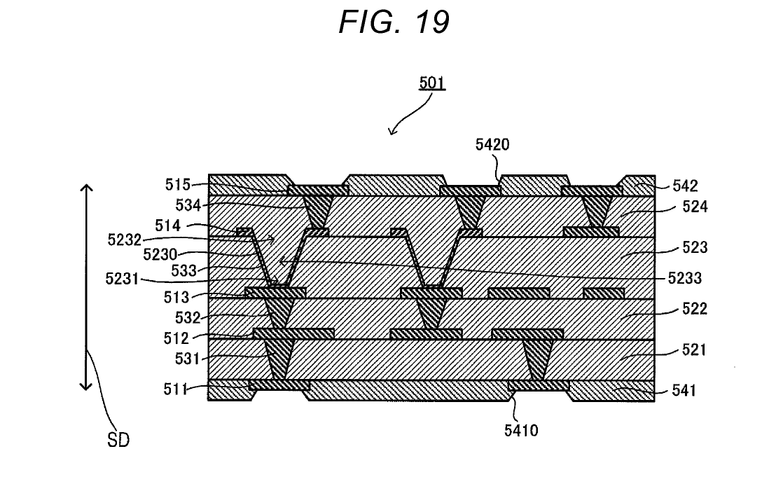

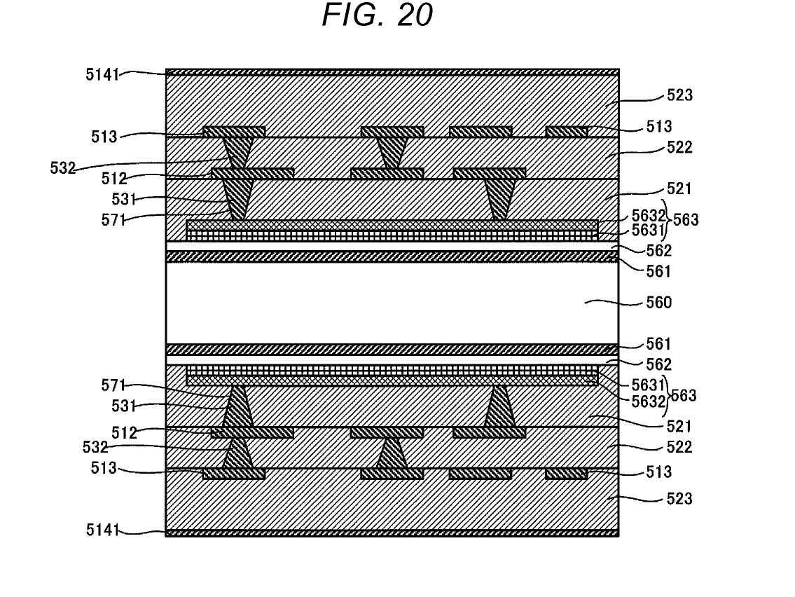

As shown in FIG. 19, a multilayer wiring substrate 501 of the third embodiment to which the invention is applied is configured such that conductor layers 511, 512, 513, 514, and 515 having a plurality of layers (five layers in the present embodiment) and insulating layers 521, 522, 523, and 524 having a number of layers (four layers in the present embodiment) which is smaller by one than that of the conductor layers 511 to 515 are alternately laminated along the lamination direction SD.

Via conductors 531, 532, and 534 formed extending in the lamination direction SD are respectively provided within the insulating layers 521, 522, and 524 constituting the multilayer wiring substrate 501. Thereby, the conductor layers 511, 512, and 514 are electrically connected to the conductor layers 512, 513, and 515, respectively.

Meanwhile, the via conductor 531 is formed in a truncated cone shape. In the via conductor 531, the diameter of the surface which comes into contact with the conductor layer 511 is smaller than the diameter of the surface which comes into contact with the conductor layer 512.

Similarly, the via conductor 532 is formed in a truncated cone shape. In the via conductor 532, the diameter of the surface which comes into contact with the conductor layer 512 is smaller than the diameter of the surface which comes into contact with the conductor layer 513. Further, the via conductor 534 is formed in a truncated cone shape. In the via conductor 534, the diameter of the surface which comes into contact with the conductor layer 514 is smaller than the diameter of the surface which comes into contact with the conductor layer 515.

In addition, a through hole 5230 for connecting the conductor layer 513 and the conductor layer 514 is formed within the insulating layer 523. A through hole conductor 533 is formed on the inner circumferential surface of the through hole 5230. Meanwhile, the through hole 5230 is formed in a truncated cone shape, and an opening 5232 on the conductor layer 514 side is larger in diameter than an opening 5231 on the conductor layer 513 side.

In addition, the conductor layer 513 is formed so as to cover the opening 5231 of the through hole 5230 facing the conductor layer 513 side. Meanwhile, the through hole conductor 533 is formed so as to cover not only the inner circumferential surface of the through hole 5230 but also the opening 5231 of the through hole 5230. For this reason, the conductor layer 513 comes into contact with the through hole conductor 533 in the entire region of the opening 5231, and thereby the conductor layer 513 and the through hole conductor 533 are electrically connected to each other.

In addition, the conductor layer 514 is formed in the periphery of the opening 5232 so as not to cover the opening 5232 of the through hole 5230 facing the conductor layer 514 side. For this reason, the conductor layer 514 comes into contact with the through hole conductor 533 along the opening end edge of the opening 5232, and thereby the conductor layer 514 and the through hole conductor 533 are electrically connected to each other. In addition, the insulating layer 524 is embedded in a bottomed hole 5233 which is formed further inside than the inner circumferential side of the through hole conductor 533 formed on the inner circumferential surface of the through hole 5230.

Further, a solder resist layer 541 is laminated at the side opposite from the insulating layer 522 with the insulating layer 521 interposed therebetween so as to cover the insulating layer 521, and a solder resist layer 542 is laminated at the side opposite from the insulating layer 523 with the insulating layer 524 interposed therebetween so as to cover the insulating layer 524. Meanwhile, the solder resist layers 541 and 542 are respectively configured such that openings 5410 and 5420 are formed in regions on which the conductor layers 511 and 515 are disposed.

Next, a method of manufacturing the multilayer wiring substrate 501 to which the invention is applied will be described.

As shown in FIG. 20, first, a supporting substrate 560 having a conductor layer 561 (copper in the present embodiment) laminated on both sides thereof is prepared. The supporting substrate 560 is, for example, a plate-like member obtained by impregnating a glass fiber with an epoxy resin, and has a high rigidity.

In a state where a release sheet 563 is disposed on the conductor layer 561 through a prepreg 562 which is an adhesive layer with respect to each of both sides of the supporting substrate 560, the release sheet 563 is compressed against the supporting substrate 560 using, for example, a vacuum hot press, to thereby laminate the release sheet 563. The release sheet 563 is formed by laminating a metal layer 5631 (copper in the present embodiment) and a metal layer 5632 (copper in the present embodiment). Meanwhile, since metal plating (for example, Cr plating) is performed between the metal layer 5631 and the metal layer 5632, the metal layer 5631 and the metal layer 5632 are laminated in a state where they can be released from each other.

Next, a photosensitive dry film is laminated on the release sheet 563 with respect to each of both sides of the supporting substrate 560, is exposed and developed after that, and is further etched, to thereby remove the outer peripheral portion of the release sheet 563. Thereafter, the dry film on the release sheet 563 is removed by etching.

In addition, a film-shaped resin material (for example, epoxy resin) is disposed on the release sheet 563 with respect to both sides of the supporting substrate 560, and the resin material is cured by pressurization and heating under vacuum, so that the insulating layer 521 is formed. Thereby, the upper part of the release sheet 563 and the upper part of the prepreg 562 in the aforementioned outer peripheral portion in which the release sheet 563 is removed are coated with the insulating layer 521.

Predetermined positions on the surface on the insulating layer 521 are then irradiated with a laser beam with respect to both sides of the supporting substrate 560, so that a plurality of via holes 571 are formed within the insulating layer 521. Further, a process (desmear process) for removing a smear generated within the via holes 571 by the formation of the via holes 571 is performed. Thereafter, electroless plating is performed, so that a thin electroless plating layer (copper in the present embodiment) is formed on the insulating layer 521. A predetermined resist pattern corresponding to a wiring pattern of the conductor layer 512 is formed on the electroless plating layer. Further, electroplating is performed, so that a plating layer (copper in the present embodiment) is formed on a region which is not covered with a resist. Thereafter, the electroless plating layer and the resist which are unnecessary are removed by etching. Thereby, the via conductor 531 is formed within the via holes 571, and the conductor layer 512 having a predetermined wiring pattern is formed.

Further, using the same process as that of forming the insulating layer 521, the conductor layer 512, and the via conductor 531, the insulating layer 522, the conductor layer 513, and the via conductor 532 are formed on the insulating layer 521.

Next, using the same process as that of forming the insulating layer 521, the insulating layer 523 is formed on the insulating layer 522. Thereafter, a conductor layer 5141 is formed on the insulating layer 523.

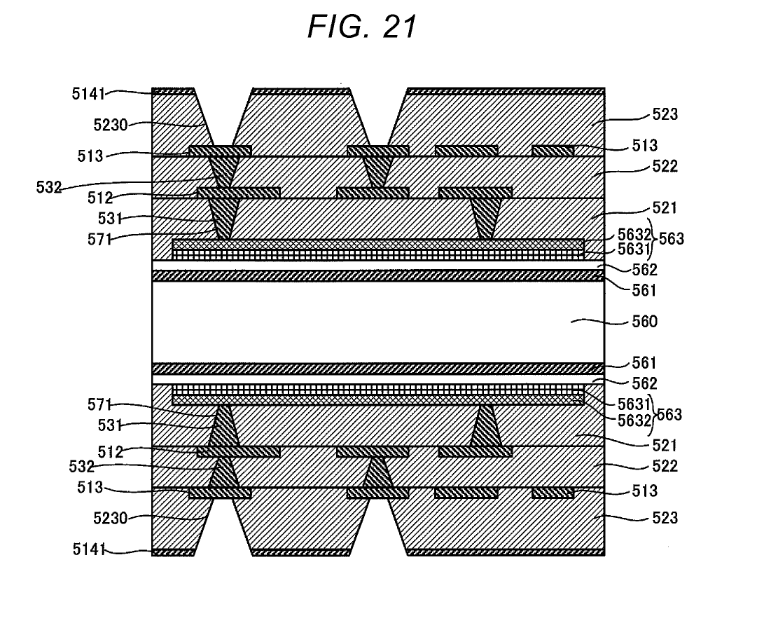

A predetermined position on the surface of the conductor layer 5141 is then irradiated with a laser beam, so that the through hole 5230 that passes through the conductor layer 5141 and reaches the conductor layer 513 is formed as shown in FIG. 21.

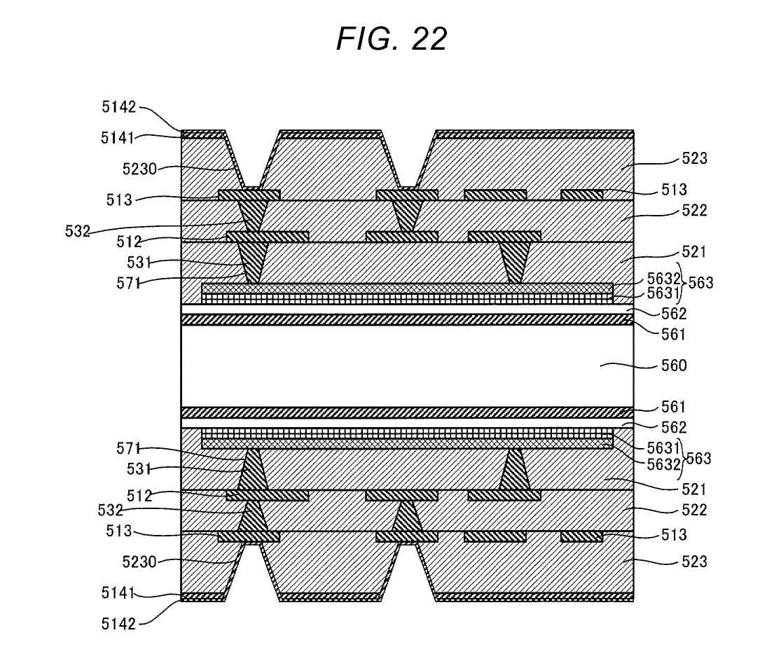

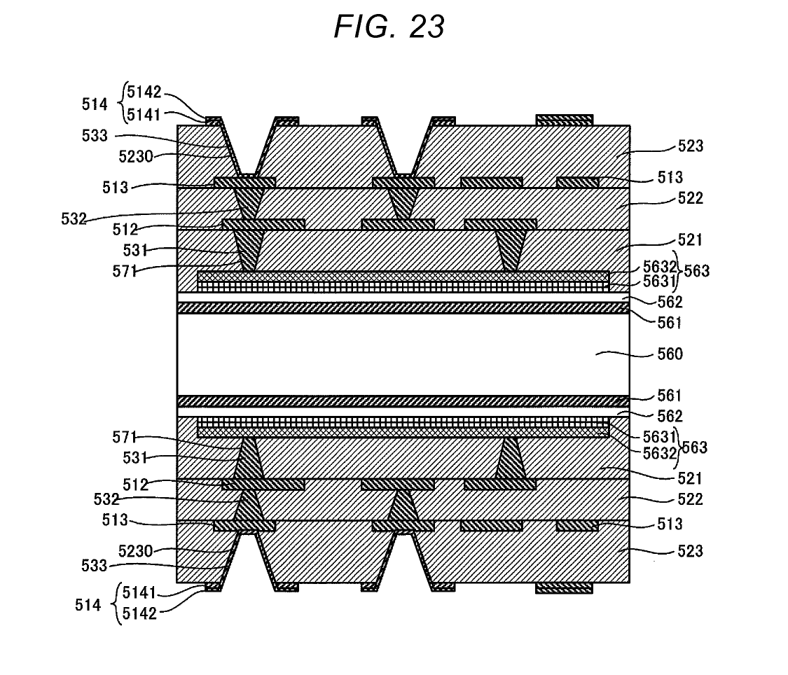

Further, a process (desmear process) for removing a smear generated within the through hole 5230 by the formation of the through hole 5230 is performed. Thereafter, electroless plating and electroplating are performed, so that a conductor layer 5142 (copper in the present embodiment) is formed on the conductor layer 5141 as shown in FIG. 22, and the conductor layer 5142 (copper in the present embodiment) is formed on the inner circumferential surface of the through hole 5230 and on the conductor layer 513. Thereafter, the conductor layers 5141 and 5142 which are unnecessary are removed using a subtractive process, so that the conductor layer 514 having a predetermined wiring pattern is formed as shown in FIG. 23. Therefore, the conductor layer 5141 and the conductor layer 5142 laminated so as to have a predetermined wiring pattern are equivalent to the conductor layer 514. In addition, the conductor layer 5142 formed on the inner circumferential surface of the through hole 5230 is equivalent to the through hole conductor 533.

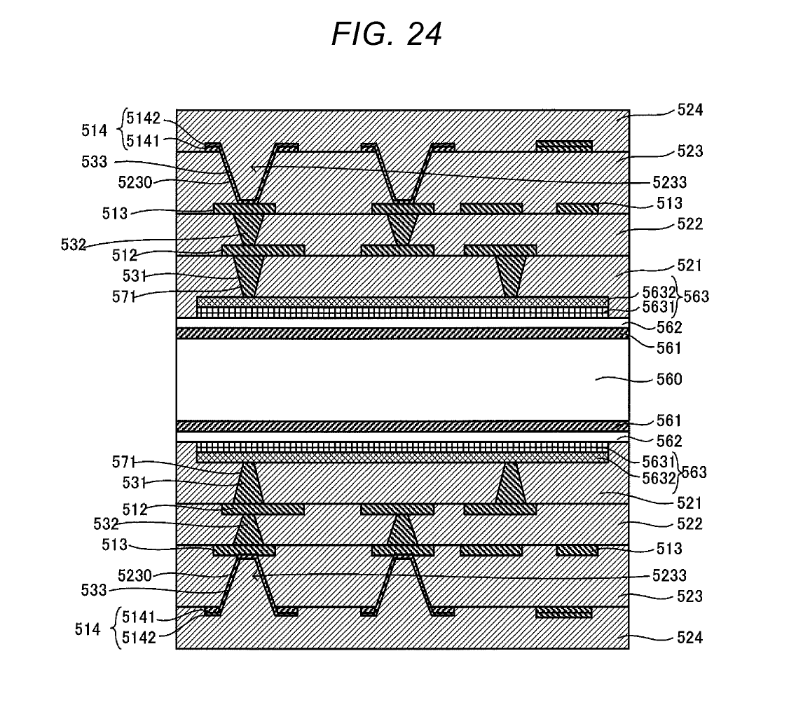

Thereafter, using the same process as that of forming the insulating layer 521, the insulating layer 524 is formed on the insulating layer 523 as shown in FIG. 24. Thereby, the insulating layer 524 is embedded in the bottomed hole 5233.

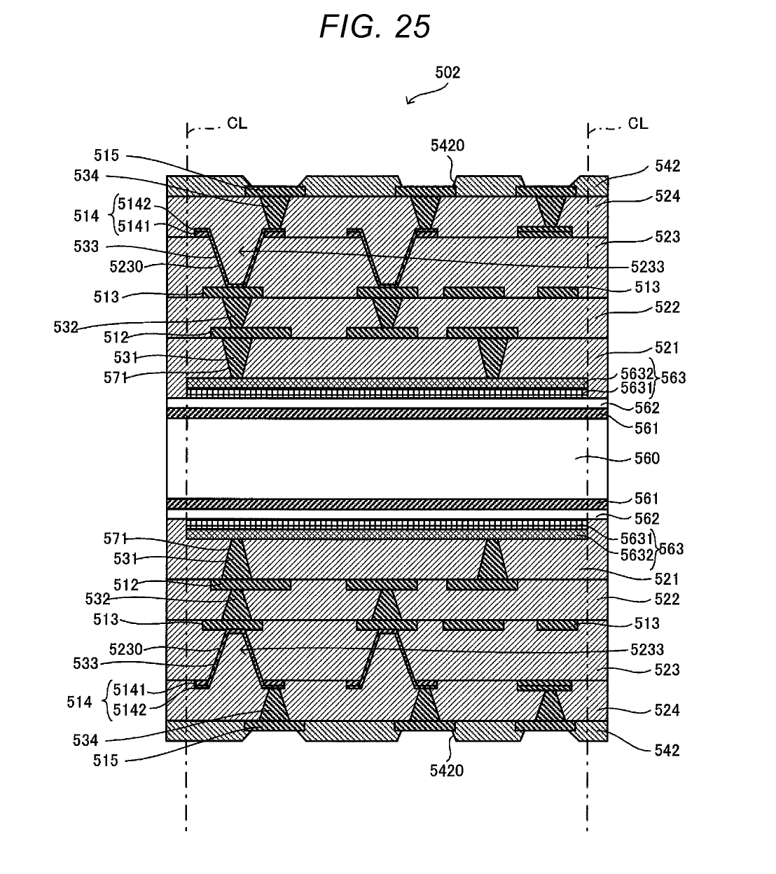

Further, using the same process as that of forming the conductor layer 512 and the via conductor 531, the via conductor 534 is formed within the insulating layer 524 as shown in FIG. 25, and the conductor layer 515 is formed on the insulating layer 524.

After a solder resist made of an organic resin material such as an epoxy resin is applied so as to cover the insulating layer 524 and the conductor layer 515, the solder resist is patterned. Thereby, the solder resist layer 542 having the opening 5420 in a region on which the conductor layer 515 is disposed is formed on the insulating layer 524.

Next, a laminate 502 in which the release sheet 563, the conductor layers 512 to 515, the insulating layers 521 to 524, and the like are laminated on the supporting substrate 560 by the aforementioned process is cut along cutting-plane lines CL which pass through the inner side more slightly than the outer peripheral edge of the release sheet 563 and are parallel to the lamination direction SD. Thereby, the outer peripheral portion of the laminate 502 is removed, and the end face on the outer peripheral portion of the release sheet 563 is exposed. For this reason, the metal layer 5631 and the metal layer 5632 can be released from the end face on the outer peripheral portion of the release sheet 563.

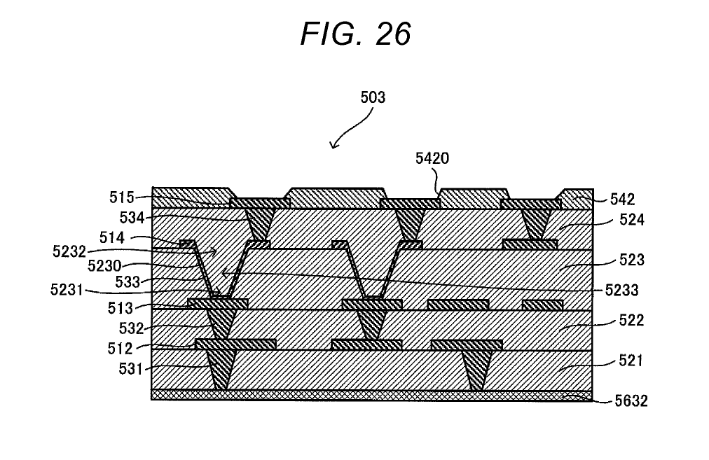

The metal layer 5631 is released from the metal layer 5632, so that a laminate 503 in which the conductor layer 512 to 515, the insulating layers 521 to 524, and the like are laminated on the metal layer 5632 is separated from the supporting substrate 560 as shown in FIG. 26. Thereby, two laminates 503 can be obtained.

Further, a photosensitive dry film is laminated on the metal layer 5632 of the laminate 503, is exposed and developed after that, and is further etched, thereby allowing the conductor layer 511 to be formed as shown in FIG. 19.

After a solder resist made of an organic resin material such as an epoxy resin is applied so as to cover the insulating layer 521 and the conductor layer 511, the solder resist is patterned. Thereby, the solder resist layer 541 having the opening 5410 in a region on which the conductor layer 511 is disposed is formed on the insulating layer 521, and thus the multilayer wiring substrate 501 can be obtained.

In the method of manufacturing the multilayer wiring substrate 501 having such a configuration, first, a build-up layer in which the insulating layers 521 and 522 and the conductor layers 512 and 513 are alternately laminated along the lamination direction SD is formed on the supporting substrate 560. The insulating layer 523 is then laminated on the conductor layer 513 constituting an outermost layer of the build-up layer, and the conductor layer 5141 is further laminated on the insulating layer 523. Thereafter, the through hole 5230 is formed which extends through the insulating layer 523 in the lamination direction SD by passing through the conductor layer 5141 and reaches the conductor layer 513 without passing through the conductor layer 513, and the through hole conductor 533 that electrically connects the conductor layer 513 and the conductor layer 5141 is further formed on the inner circumferential surface of the through hole 5230. After the through hole conductor 533 is formed, the conductor layer 5141 is patterned so that a wiring pattern which is set in advance is formed. Thereafter, the insulating layer 524 is laminated on the insulating layer 523, and the inner side of the through hole conductor 533 and the through hole formed in the conductor layer 5141 are filled with a portion of the insulating layer 524.

In this manner, the insulating layer 524 is laminated on the insulating layer 523, whereby inside the through hole 5230 can be embedded the insulating layer 524. Thereby, it is possible to eliminate the need for a special process for embedding inside the through hole 5230.

In addition, the through hole 5230 is formed so as to reach the conductor layer 513 without passing through the conductor layer 513. That is, the opening 5231 of the through hole 5230 is covered by the conductor layer 513. For this reason, the via conductor 532 can be disposed directly above the opening 5231 of the through hole 5230 through the conductor layer 513.

In the embodiment described, the supporting substrate 560 is a base substrate in the invention, the laminate in which the insulating layers 521 and 522 and the conductor layers 512 and 513 are alternately laminated is an underlying laminate in the invention, the conductor layer 513 is a third conductor layer in the invention, the insulating layer 523 is an intermediate insulating layer in the invention, the conductor layer 5141 is a fourth conductor layer in the invention, and the insulating layer 524 is an insulating layer located on the intermediate insulating layer in the invention.

### Fourth Embodiment

Hereinafter, a fourth embodiment of the invention will be described. Meanwhile, in the fourth embodiment, portions different from those of the third embodiment will be described below.

The multilayer wiring substrate 501 of the fourth embodiment is the same as that of the third embodiment, except that a manufacturing method is changed.

Next, a method of manufacturing the multilayer wiring substrate 501 of the fourth embodiment will be described.

First, the process until the insulating layer 523 is formed on the insulating layer 522 is the same as that of the third embodiment.

After the insulating layer 523 is formed, a predetermined position on the surface of the insulating layer 523 is irradiated with a laser beam, so that the through hole 5230 reaching the conductor layer 513 is formed.

Further, a process (desmear process) for removing a smear generated within the through hole 5230 by the formation of the through hole 5230 is performed. Thereafter, electroless plating and electroplating are performed, so that the conductor layer 514 (copper in the present embodiment) is formed on the insulating layer 523, and the conductor layer 514 is formed on the inner circumferential surface of the through hole 5230 and on the conductor layer 513. Thereafter, the conductor layer 514 which is unnecessary is removed using a subtractive process, so that the conductor layer 514 having a predetermined wiring pattern is formed. Meanwhile, the conductor layer 514 formed on the inner circumferential surface of the through hole 5230 is equivalent to the through hole conductor 533.

Thereafter, using the same process as that of forming the insulating layer 521, the insulating layer 524 is formed on the insulating layer 523. Thereby, the insulating layer 524 is embedded in the bottomed hole 5233.

Processes after that are the same as those of the third embodiment.

In the method of manufacturing the multilayer wiring substrate 501 having such a configuration, first, a build-up layer in which the insulating layers 521 and 522 and the conductor layers 512 and 513 are alternately laminated along the lamination direction SD is formed on the supporting substrate 560. The insulating layer 523 is then laminated on the conductor layer 513 constituting an outermost layer of the build-up layer. Thereafter, the through hole 5230 is formed which extends through the insulating layer 523 in the lamination direction SD and reaches the conductor layer 513 without passing through the conductor layer 513, and a conductor layer is further laminated on the insulating layer 523 and on the inner circumferential surface of the through hole 5230. Thereby, the conductor layer 514 is formed on the insulating layer 523, and the through hole conductor 533 is formed on the inner circumferential surface of the through hole 5230. After the through hole conductor 533 is formed, the conductor layer 514 is patterned so that a wiring pattern set in advance is formed. Thereafter, the insulating layer 524 is laminated on the insulating layer 523, and the inner side of the through hole conductor 533 is filled with a portion of the insulating layer 524.

In this manner, the insulating layer 524 is laminated on the insulating layer 523, whereby inside the through hole 5230 can be embedded the insulating layer 524. Thereby, it is possible to eliminate the need for a special process for embedding inside the through hole 5230.

In addition, the through hole 5230 is formed so as to reach the conductor layer 513 without passing through the conductor layer 513. That is, the opening 5231 of the through hole 5230 is covered by the conductor layer 513. For this reason, the via conductor 532 can be disposed directly above the opening 5231 of the through hole 5230 through the conductor layer 513.

In the embodiment described above, the supporting substrate 560 is a base substrate in the invention, the laminate in which the insulating layers 521 and 522 and the conductor layers 512 and 513 are alternately laminated is an underlying laminate in the invention, the conductor layer 513 is a third conductor layer in the invention, the insulating layer 523 is an intermediate insulating layer in the invention, the conductor layer 514 is a fourth conductor layer in the invention, and the insulating layer 524 is an insulating layer located on the intermediate insulating layer in the invention.

As stated above, although each of the embodiments of the invention has been described, the invention is not limited to the aforementioned embodiments, but can be modified variously within the technical scope of the invention.

What is claimed is:

1. A multilayer wiring substrate, comprising:
a first build-up layer and a second build-up layer which are each formed by laminating at least one insulating layer and at least one conductor layer;
a supporting substrate that supports the first build-up layer and the second build-up layer on an upper surface and a lower surface thereof, respectively;
a through hole which is formed to extend between the upper surface side of the supporting substrate and the lower surface side thereof, and including an opening on an upper end side of the through hole that has a larger diameter than that of an opening on a lower end side of the through hole;
a through hole conductor which is formed on an inner circumferential surface of the through hole;
a coating conductor which is formed so as to cover the opening on the upper end side of the through hole, and is electrically connected to the through hole conductor; and
a non-coating conductor which is formed in a periphery of the opening on the lower end side of the through hole without covering the opening on the lower end side, and is electrically connected to the through hole conductor.

2. The multilayer wiring substrate according to claim 1, further comprising:
a via conductor electrically connected to a side of the coating conductor that is opposite from the through hole conductor, and disposed so that at least a portion of a surface of the via conductor that comes into contact with the coating conductor faces the opening on the upper end side of the through hole.

3. The multilayer wiring substrate according to claim 2, wherein a center of the surface of the via conductor which comes into contact with the coating conductor coincides with a center of the opening on the upper end side of the through hole.

4. A method of manufacturing a multilayer wiring substrate including a first build-up layer and a second build-up layer which are formed by laminating at least one insulating layer and at least one conductor layer, and a supporting substrate that supports the first build-up layer and the second build-up layer on an upper surface and a lower surface thereof, respectively, the method comprising:
a first process of forming a through hole on a substrate that includes a supporting substrate insulating layer constituting the supporting substrate, a first conductor layer formed throughout the entirety of the upper surface of the supporting substrate insulating layer, and a second conductor layer formed throughout the entirety of the lower surface of the supporting substrate insulating layer, the through hole extending between the upper surface of the supporting substrate insulating layer and the lower surface thereof by passing through the second conductor layer and reaching the first conductor layer without passing through the first conductor layer;
a second process of forming a through hole conductor, which electrically connects the first conductor layer and the second conductor layer, on an inner circumferential surface of the through hole;
a third process of patterning the first conductor layer and the second conductor layer so that a wiring pattern which is set in advance is formed, after the through hole conductor is formed through the second process; and
a fourth process of laminating an insulating layer on the supporting substrate insulating layer after the wiring pattern is formed through the third process, and filling an inner side of the through hole conductor and the through hole formed in the second conductor layer with a portion of the insulating layer.

5. A method of manufacturing a multilayer wiring substrate, comprising:
a process of forming, on a base substrate, an underlying laminate in which at least one insulating layer and at least one conductor layer are alternately laminated along a lamination direction which is set in advance;
a process of laminating an intermediate insulating layer on a third conductor layer constituting an outermost layer of the underlying laminate, and further laminating a fourth conductor layer on the intermediate insulating layer;
a process of forming a through hole which extends through the intermediate insulating layer in the lamination direction by passing through the fourth conductor layer and reaching the third conductor layer without passing through the third conductor layer;
a process of forming a through hole conductor, which electrically connects the third conductor layer and the fourth conductor layer, on an inner circumferential surface of the through hole;
a process of patterning the fourth conductor layer so that a wiring pattern which is set in advance is formed, after the through hole conductor is formed; and
a process of laminating an insulating layer on the intermediate insulating layer after the wiring pattern is formed, and filling an inner side of the through hole conductor and the through hole formed in the fourth conductor layer with a portion of the insulating layer.

6. A method of manufacturing a multilayer wiring substrate, comprising:
a process of forming, on a base substrate, an underlying laminate in which at least one insulating layer and at least one conductor layer are alternately laminated along a lamination direction which is set in advance;
a process of laminating an intermediate insulating layer on a third conductor layer constituting an outermost layer of the underlying laminate;
a process of forming a through hole which extends through the intermediate insulating layer in the lamination direction and reaches the third conductor layer without passing through the third conductor layer;
a process of laminating a metal layer on the intermediate insulating layer and on an inner circumferential surface of the through hole to form a fourth conductor layer on the intermediate insulating layer and form a through hole conductor on the inner circumferential surface of the through hole;
a process of patterning the fourth conductor layer so that a wiring pattern which is set in advance is formed, after the through hole conductor is formed; and
a process of laminating an insulating layer on the intermediate insulating layer after the wiring pattern is formed, and filling an inner side of the through hole conductor with a portion of the insulating layer.
